(19) United States
(12) Patent Application Publication
(10) Pub. No.: US 2025/0296637 A1
(43) Pub. Date: Sep. 25, 2025

(54) FUNCTIONAL ROOF AND MANUFACTURING METHOD THEREOF

(71) Applicant: KABUSHIKI KAISHA TOYOTA JIDOSHOKKI, Kariya-shi, Aichi-ken (JP)

(72) Inventors: Masaki AGEMI, Kariya-shi, Aichi-ken (JP); Yuya MARUYAMA, Kariya-shi, Aichi-ken (JP)

(73) Assignee: KABUSHIKI KAISHA TOYOTA JIDOSHOKKI, Kariya-shi, Aichi-ken (JP)

(21) Appl. No.: 18/863,401

(22) PCT Filed: Dec. 26, 2022
(86) PCT No.: PCT/JP2022/047955

§ 371 Date: Nov. 6, 2024

(30) Foreign Application Priority Data
May 12, 2022 (JP) 2022-078686

(51) Int. Cl. B62D 25/06; B32B 3/04; B32B 3/30; B32B 7/022; B32B 27/08; B32B 37/06; B32B 37/10; B32B 37/18; B32B 37/24; H02S 20/30

(52) U.S. Cl. CPC B62D 25/06; B32B 3/04; B32B 3/30; B32B 7/022; B32B 27/08; B32B 37/06; B32B 37/10; B32B 37/182; B32B 37/24; H02S 20/30; B32B 2037/243; B32B 2255/10; B32B 2307/412; B32B 2307/546; B32B 2605/00

(57) ABSTRACT

A functional roof includes a functional layer, a sealing layer, a front surface protecting material composed of resin with light transmittance, a back surface protecting material, and a barrier layer. The barrier layer includes a front-side barrier sheet and a back-side barrier sheet. The front-side barrier sheet includes a front surface covering portion and the back-side barrier sheet includes a back surface covering portion. The front-side barrier sheet includes a front-side protruding portion and the front-side protruding portion is joined to the back-side barrier sheet in a state of covering a surrounding end surface, or the back-side barrier sheet includes a back-side protruding portion and the back-side protruding portion is joined to the front-side barrier sheet in a state of covering the surrounding end surface.

### TECHNICAL FIELD

The present disclosure relates to a functional roof and a manufacturing method thereof.

### BACKGROUND ART

A functional roof (such as a solar photovoltaic panel or a light control roof) provided on the upper surface of a vehicle is known so far. For example, Japanese Patent Laying-Open No. 2014-207362 discloses a solar battery that includes a solar battery cell, a sealing material protecting the solar battery cell, a light transmission member provided on a front surface of the sealing material, a back sheet provided on a back surface of the sealing material, and a first gas barrier sheet and a second gas barrier sheet provided along an outer edge of the sealing material.

### CITATION LIST

### Patent Literature

Japanese Patent Laying-Open No. 2014-207362

### SUMMARY OF INVENTION

### Technical Problem

When in the solar battery described in Japanese Patent Laying-Open No. 2014-207362, the light transmission member is formed of resin for weight reduction, there is concern that air bubbles will be caused in the sealing material by gas or water vapor passing through the light transmission member and reaching the sealing material. Similarly, there is concern that air bubbles will be caused in the sealing material by gas or water vapor passing through the back sheet and reaching the sealing material.

An object of the present invention is to provide a functional roof and a manufacturing method thereof that enable it to inhibit occurrence of air bubbles in a sealing layer.

### Solution to Problem

A functional roof according to an aspect of the present disclosure includes: a functional layer having a predetermined function; a sealing layer sealing the functional layer and including a front surface, a back surface, and a surrounding end surface that links the front surface and the back surface and surrounds a periphery of the functional layer in a ring manner; a front surface protecting material composed of resin with light transmittance and protecting the front surface of the sealing layer; a back surface protecting material protecting the back surface of the sealing layer; and a barrier layer covering the sealing layer, the barrier layer includes a front-side barrier sheet situated between the sealing layer and the front surface protecting material, and a back-side barrier sheet situated between the sealing layer and the back surface protecting material, the front-side barrier sheet includes a front surface covering portion covering an entire region of the front surface of the sealing layer, the back-side barrier sheet includes a back surface covering portion covering an entire region of the back surface of the sealing layer, and the front-side barrier sheet includes a front-side protruding portion protruding from an edge portion of the front surface covering portion and situated away from the front surface protecting material and the front-side protruding portion is joined to the back-side barrier sheet in a state of covering the surrounding end surface, or the back-side barrier sheet includes a back-side protruding portion protruding from an edge portion of the back surface covering portion and situated away from the back surface protecting material and the back-side protruding portion is joined to the front-side barrier sheet in a state of covering the surrounding end surface.

Further, a manufacturing method of a functional roof according to an aspect of the present disclosure, which includes a functional layer having a predetermined function, a sealing layer sealing the functional layer, a front surface protecting material composed of resin with light transmittance and protecting a front surface of the sealing layer, a back surface protecting material protecting a back surface of the sealing layer, and a barrier layer covering the sealing layer, the barrier layer including a front-side barrier sheet situated between the sealing layer and the front surface protecting material, and a back-side barrier sheet situated between the sealing layer and the back surface protecting material, includes: a stack forming step of forming a stack by stacking the front surface protecting material, the front-side barrier sheet, a plurality of sealing layer forming materials constituting the sealing layer and the functional layer situated in the plurality of sealing layer forming materials, the back-side barrier sheet, and the back surface protecting material; a uniting step of forming the sealing layer sealing the functional layer by heating the stack and thus softening the plurality of sealing layer forming materials, and of forming the barrier layer covering the sealing layer by joining the front-side barrier sheet and the back-side barrier sheet to each other; and a hot press step of, after the uniting step, pressing the front surface protecting material, the sealing layer, the barrier layer, and the back surface protecting material while heating the front surface protecting material, the sealing layer, the barrier layer, and the back surface protecting material so that the front surface protecting material, the sealing layer, the barrier layer, and the back surface protecting material have a shape bending so as to project toward one side in a direction in which the front surface protecting material, the sealing layer, the barrier layer, and the back surface protecting material are stacked.

### Advantageous Effects of Invention

The present disclosure can provide a functional roof and a manufacturing method thereof that enable it to inhibit occurrence of air bubbles in a sealing layer.

### BRIEF DESCRIPTION OF DRAWINGS

FIG. 1 is a plan view schematically illustrating a functional roof according to an embodiment of the present disclosure.

FIG. 2 is a cross-sectional view along line II-II in FIG. 1.

FIG. 3 is a cross-sectional view schematically illustrating a manufacturing method of the functional roof.

FIG. 4 is a diagram schematically illustrating a variation of the functional roof.

FIG. 5 is a diagram schematically illustrating a variation of the functional roof.

FIG. 6 is a diagram schematically illustrating a variation of the functional roof.

FIG. 7 is a diagram schematically illustrating a variation of the functional roof.

FIG. 8 is a diagram schematically illustrating a variation of the functional roof.

### DESCRIPTION OF EMBODIMENTS

Embodiments of the present invention are described with reference to the drawings In the drawings referred to below, the same numerals are given to identical or equivalent members.

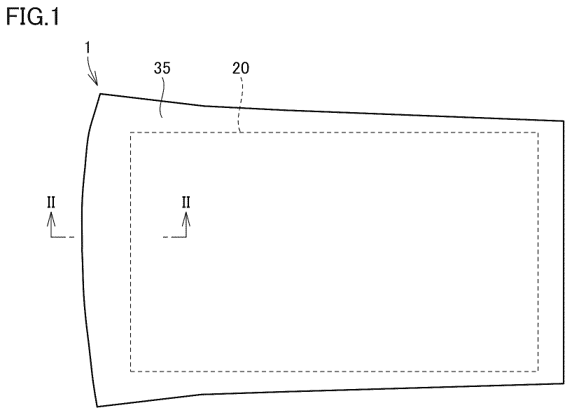

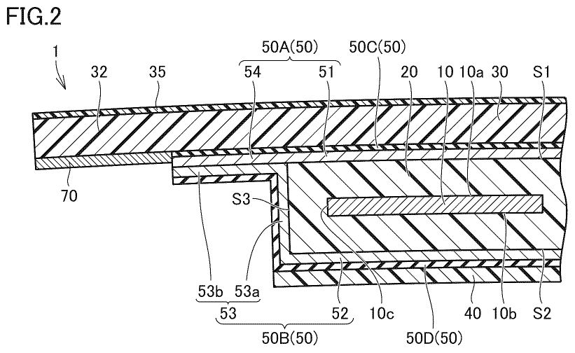

FIG. 1 is a diagram schematically illustrating a functional roof according to an embodiment of the present disclosure. FIG. 2 is a cross-sectional view along line II-II in FIG. 1. The functional roof 1 is preferably used on a vehicle.

As illustrated in FIGS. 1 and 2, the functional roof 1 includes a functional layer 10, a sealing layer 20, a front surface protecting material 30, a hard coat layer 35, a back surface protecting material 40, a barrier layer 50, and a shield portion 70.

The functional layer 10 has a predetermined function. Examples of the predetermined function include a power generation function, a light control function, a display function, and the like. When the predetermined function is a power generation function, the functional layer 10 is constituted of a solar photovoltaic panel. When the predetermined function is a light control function, the functional layer 10 is constituted of a light control film (a film capable of adjusting light transmissivity through application of voltage). When the predetermined function is a display function, the functional layer 10 is constituted of a display (of LED, organic EL, liquid crystal, or the like).

As illustrated in FIG. 2, the functional layer 10 is formed like an approximately flat plate. The functional layer 10 includes a first main surface 10a, a second main surface 10b, and an end surface 10c. The first main surface 10a is a surface formed on one side of the functional layer 10 (the upper side in FIG. 2) in its thickness direction (the up-and-down direction in FIG. 2). The first main surface 10a is formed so as to be substantially flat. The second main surface 10b is a surface formed on the other side in the thickness direction of the functional layer 10. The second main surface 10b is formed so as to be substantially flat. The end surface 10c links the first main surface 10a and the second main surface 10b and is contiguous in a ring manner.

The sealing layer 20 seals the functional layer 10. More specifically, the sealing layer 20 seals the entire region of the first main surface 10a, the entire region of the second main surface 10b, and the entire region of the end surface 10c of the functional layer 10. The sealing layer 20 is composed of resin with light transmittance. The sealing layer 20 is composed of, for example, ethylene-vinyl acetate (EVA), polyolefin, silicone, or ionomer. The sealing layer 20 is formed by heating the sheets composed of the aforementioned resins (sealing layer forming materials) in a state where the sheets are stacked.

The sealing layer 20 includes a front surface S1, a back surface S2, and a surrounding end surface S3. The front surface S1 is provided on one side of the functional layer 10 in the thickness direction of the functional layer 10 and constituted of a main surface on one side of the sealing layer 20. The back surface S2 is provided on the other side of the functional layer 10 in the thickness direction of the functional layer 10 and constituted of a main surface on the other side of the sealing layer 20. The surrounding end surface S3 links the front surface S1 and the back surface S2 and surrounds the periphery of the functional layer 10 in a ring manner.

The front surface protecting material 30 protects the front surface S1 of the sealing layer 20. The front surface protecting material 30 is provided on one side of the sealing layer 20 (the upper side in FIG. 2) with interposition of a front-side barrier sheet 50A and a front-side adhesion layer 50C, which are described later. The front surface protecting material 30 is composed of resin with light transmittance. The front surface protecting material 30 is composed of, for example, polycarbonate (PC), polymethyl methacrylate (PMMA), polyethylene terephthalate (PET), or polypropylene (PP).

The hard coat layer 35 is provided on a front surface of the front surface protecting material 30. The hard coat layer 35 is composed of a material higher in hardness than the material of which the front surface protecting material 30 is composed, and covers the front surface of the front surface protecting material 30.

The hard coat layer 35 is composed of a material with light transmittance.

The back surface protecting material 40 protects the back surface S2 of the sealing layer 20. The back surface protecting material 40 is provided on the other side of the sealing layer 20 (the lower side in FIG. 2) with interposition of a back-side barrier sheet 50B and a back-side adhesion layer 50D, which are described later. The outside shape of the back surface protecting material 40 in a plan view is made approximately the same as the outside shape of the back surface S2 of the sealing layer 20 in a plan view. The thickness of the back surface protecting material 40 is smaller than the thickness of the front surface protecting material 30. The flexural rigidity of the front surface protecting material 30 is higher than the flexural rigidity of the back surface protecting material 40. When the functional layer 10 is constituted of a light control film, the back surface protecting material 40 is formed of a material with light transmittance. The back surface protecting material 40 is composed of, for example, polycarbonate (PC), ABS resin, or a composite material of these.

The barrier layer 50 covers the sealing layer 20. The barrier layer 50 is composed of a material (such as a resin material) that prevents gas or water vapor from passing therethrough. The barrier layer 50 is formed like a film (a thin film). As illustrated in FIG. 2, the barrier layer 50 includes the front-side barrier sheet 50A, the back-side barrier sheet 50B, the front-side adhesion layer 50C, and the back-side adhesion layer 50D.

The front-side barrier sheet 50A is situated between the sealing layer 20 and the front surface protecting material 30. The front-side barrier sheet 50A is composed of a material with light transmittance. The front-side barrier sheet 50A includes a front surface covering portion 51 and a front-side extension portion 54.

The front surface covering portion 51 covers the entire region of the front surface S1 of the sealing layer 20. The outside shape of the front surface covering portion 51 in a plan view substantially corresponds to the outside shape of the front surface S1 of the sealing layer 20 in a plan view.

The front-side extension portion 54 extends from an edge portion of the front surface covering portion 51 and is joined to the front surface protecting material 30. That is, the front-side extension portion 54 is formed in a position where the front-side extension portion 54 does not overlap the sealing layer 20 in the thickness direction of the functional roof 1 (the up-and-down direction in FIG. 2).

The front-side adhesion layer 50C is provided on the entire region of a front surface of the front-side barrier sheet 50A and causes the front-side barrier sheet 50A to adhere to the front surface protecting material 30. The front-side adhesion layer 50C is composed of a material with light transmittance (such as synthetic resin). The outside shape of the front-side adhesion layer 50C is substantially the same as the outside shape of the front-side barrier sheet 50A.

The back-side barrier sheet 50B is situated between the sealing layer 20 and the back surface protecting material 40. When the functional layer 10 is constituted of a light control film, the back-side barrier sheet 50B is composed of a material with light transmittance. The back-side barrier sheet 50B includes a back surface covering portion 52 and a back-side protruding portion 53.

The back surface covering portion 52 covers the entire region of the back surface S2 of the sealing layer 20. The outside shape of the back surface covering portion 52 in a plan view substantially corresponds to the outside shape of the back surface S2 of the sealing layer 20 in a plan view.

The back-side protruding portion 53 protrudes from an edge portion of the back surface covering portion 52. The back-side protruding portion 53 is situated away from the back surface protecting material 40. The back-side protruding portion 53 is joined to the front-side barrier sheet 50A in a state of covering the surrounding end surface S3 of the sealing layer 20. The back-side protruding portion 53 includes an end surface covering portion 53a and a back-side sheet end portion 53b.

The end surface covering portion 53a is contiguous to the edge portion of the back surface covering portion 52 and covers the surrounding end surface S3 of the sealing layer 20. A space may be formed between the end surface covering portion 53a and the surrounding end surface S3.

The back-side sheet end portion 53b is joined to the front-side barrier sheet 50A. In the present embodiment, the back-side sheet end portion 53b is joined to the front-side extension portion 54.

The back-side adhesion layer 50D is provided on the entire region of a back surface of the back-side barrier sheet 50B and causes the back-side barrier sheet 50B to adhere to the back surface protecting material 40. When the functional layer 10 is constituted of a light control film, the back-side adhesion layer 50D is composed of a material with light transmittance (such as synthetic resin). The outside shape of the back-side adhesion layer 50D is substantially the same as the outside shape of the back-side barrier sheet 50B.

The shield portion 70 is composed of a black material (such as a ceramic). In the present embodiment, the shield portion 70 is provided on a back surface of the front surface protecting material 30. More specifically, the front surface protecting material 30 includes a flange portion 32 protruding outward from a portion that overlaps the sealing layer 20 in the thickness direction, and the shield portion 70 is provided on a back surface of the flange portion 32.

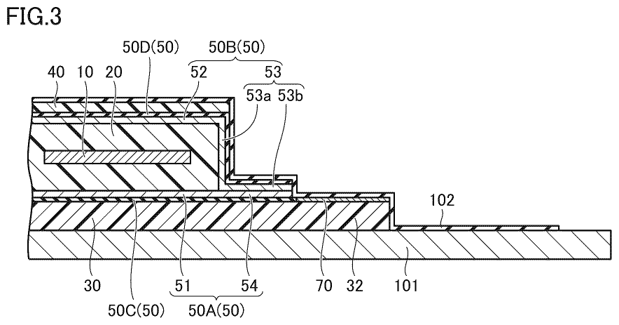

A manufacturing method of the functional roof 1 is described next with reference to FIG. 3. This manufacturing method includes a stack forming step, a uniting step, and a hot press step.

In the stack forming step, a stack is formed by stacking the front surface protecting material 30, the front-side barrier sheet 50A, the plurality of sealing layer forming materials constituting the sealing layer 20 and the functional layer 10 situated in the plurality of sealing layer forming materials, the back-side barrier sheet 50B, and the back surface protecting material 40. More specifically, in the stack forming step, a stack is formed by stacking the front surface protecting material 30 provided with the hard coat layer 35, the front-side adhesion layer 50C, the front-side barrier sheet 50A, the plurality of sealing layer forming materials and the functional layer 10, the back-side barrier sheet 50B, the back-side adhesion layer 50D, and the back surface protecting material 40.

In the stack forming step, prior to the formation of the stack, the front surface protecting material 30 provided with the hard coat layer 35, the front-side adhesion layer 50C, and the front-side barrier sheet 50A may be united in advance by being heated. Similarly, prior to the formation of the stack, the back surface protecting material 40 and the back surface covering portion 52 of the back-side barrier sheet 50B may be united in advance by being heated.

In the uniting step, the sealing layer 20 sealing the functional layer 10 is formed by heating the stack and thus softening the plurality of sealing layer forming materials, and the barrier layer 50 covering the sealing layer 20 is formed by joining the front-side barrier sheet 50A and the back-side barrier sheet 50B to each other. As illustrated in FIG. 3, in the uniting step, for example, the stack is united by causing the space between a plate-like member 101 and a sheet 102 to be a vacuum in a state where the stack is placed on the plate-like member 101 heated and the stack is covered with the sheet 102 composed of rubber. In the uniting step, the front-side extension portion 54 of the front-side barrier sheet 50A and the back-side sheet end portion 53b of the back-side barrier sheet 50B are joined to each other. Thus, the end surface covering portion 53a covering the surrounding end surface S3 of the sealing layer 20 is formed.

The hot press step is performed after the uniting step. In the hot press step, the hard coat layer 35, the front surface protecting material 30, the sealing layer 20, the barrier layer 50, and the back surface protecting material 40 are pressed while heated so that the hard coat layer 35, the front surface protecting material 30, the sealing layer 20, the barrier layer 50, and the back surface protecting material 40 have a shape bending so as to project toward one side in the stacking direction thereof, more specifically, from the back surface protecting material 40 toward the front surface protecting material 30.

As described above, in the functional roof 1 of the present embodiment, the barrier layer 50 includes the front surface covering portion 51, the back surface covering portion 52, and the end surface covering portion 53a and accordingly, occurrence of air bubbles in the sealing layer 20 caused by gas or water vapor entering the sealing layer 20 is inhibited.

Additionally, since the back-side protruding portion 53 is situated away from the back surface protecting material 40, the outside shape of the back surface protecting material 40 in a plan view can be made smaller to be approximately the same in size as the outside shape of the back surface S2 of the sealing layer 20 in a plan view.

Variations of the foregoing embodiment are described next.

### (First Variation)

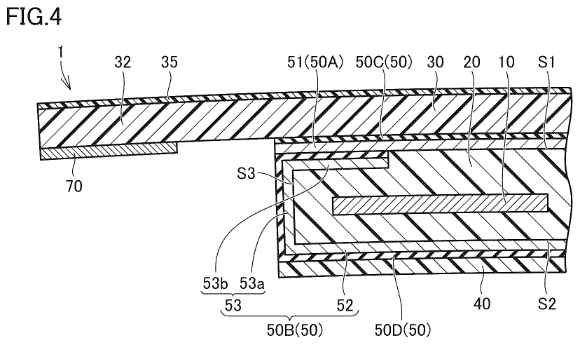

As illustrated in FIG. 4, the back-side sheet end portion 53b may be situated between the front surface covering portion 51 and the sealing layer 20. In this case, the front-side extension portion 54 may be dispensed with and the front-side barrier sheet 50A may be constituted of the front surface covering portion 51 only. In this example, the front-side barrier sheet 50A and the back-side barrier sheet 50B are joined to each other with interposition of the back-side adhesion layer 50D and thus, airtightness is increased.

### (Second Variation)

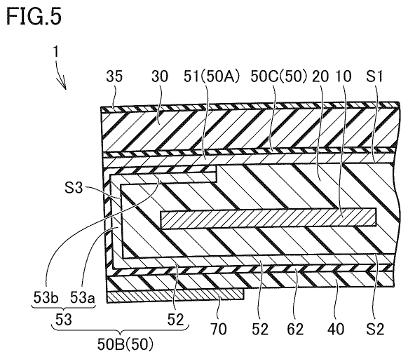

As illustrated in FIG. 5, the back-side sheet end portion 53b may be situated between the front surface covering portion 51 and the sealing layer 20, and the shield portion 70 may be provided on a back surface of the back surface protecting material 40. Also in this example, the front-side extension portion 54 may be dispensed with and the front-side barrier sheet 50A may be constituted of the front surface covering portion 51 only. Further, in this example, the flange portion 32 of the front surface protecting material 30 may be dispensed with.

### (Third Variation)

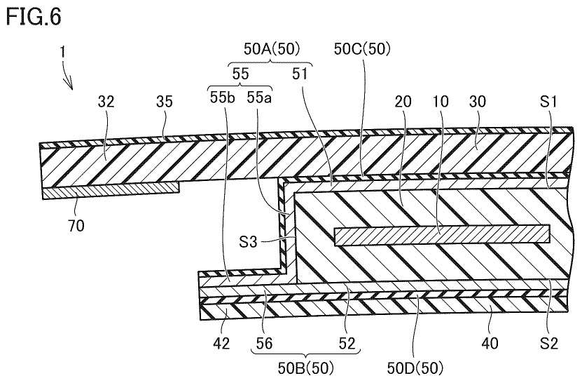

As illustrated in FIG. 6, the back-side protruding portion 53 may be dispensed with in the back-side barrier sheet 50B, and the front-side barrier sheet 50A may include a front-side protruding portion 55 instead of the front-side extension portion 54. The front-side protruding portion 55 protrudes from the edge portion of the front surface covering portion 51 and is situated away from the front surface protecting material 30. The front-side protruding portion 55 is joined to the back-side barrier sheet 50B in a state of covering the surrounding end surface S3. The front-side protruding portion 55 includes an end surface covering portion 55a and a front-side sheet end portion 55b.

The end surface covering portion 55a is contiguous to the edge portion of the front surface covering portion 51 and covers the surrounding end surface S3 of the sealing layer 20. A space may be formed between the end surface covering portion 55a and the surrounding end surface S3.

The front-side sheet end portion 55b is joined to the back-side barrier sheet 50B. In this example, while the back surface protecting material 40 includes a flange portion 42 protruding outward from a portion that overlaps the sealing layer 20 in the thickness direction, the back-side barrier sheet 50B includes a back-side extension portion 56 extending from the edge portion of the back surface covering portion 52 and joined to the flange portion 42, and the front-side sheet end portion 55b is joined to the back-side extension portion 56.

### (Fourth Variation)

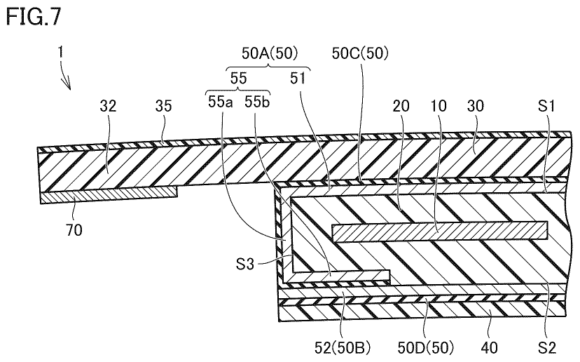

As illustrated in FIG. 7, the front-side sheet end portion 55b may be situated between the back surface covering portion 52 and the sealing layer 20. In this case, the back-side extension portion 56 may be dispensed with and the back-side barrier sheet 50B may be constituted of the back surface covering portion 52 only. In this example, the front-side barrier sheet 50A and the back-side barrier sheet 50B are joined to each other with interposition of the front-side adhesion layer 50C and thus, airtightness is increased similarly to the first variation.

### (Fifth Variation)

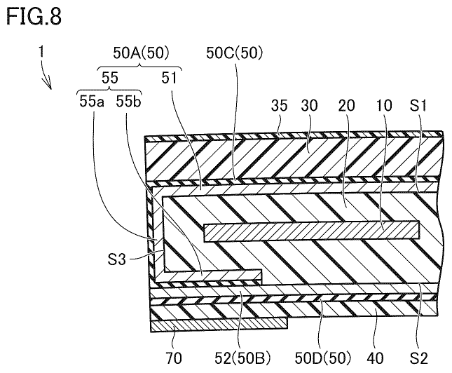

As illustrated in FIG. 8, the front-side sheet end portion 55b may be situated between the back surface covering portion 52 and the sealing layer 20, and the shield portion 70 may be provided on the back surface of the back surface protecting material 40. Also in this case, the back-side extension portion 56 may be dispensed with and the back-side barrier sheet 50B may be constituted of the back surface covering portion 52 only. Further, in this example, the flange portion 32 of the front surface protecting material 30 may be dispensed with.

### Aspects

Those skilled in the art will understand that the above-described exemplary embodiments are specific examples of the following aspects.

### (Aspect 1)

A functional roof comprising:
a functional layer having a predetermined function;
a sealing layer sealing the functional layer and including a front surface, a back surface, and a surrounding end surface that links the front surface and the back surface and surrounds a periphery of the functional layer in a ring manner;
a front surface protecting material composed of resin with light transmittance and protecting the front surface of the sealing layer;
a back surface protecting material protecting the back surface of the sealing layer; and
a barrier layer covering the sealing layer, wherein
the barrier layer includes
   a front-side barrier sheet situated between the sealing layer and the front surface protecting material, and
   a back-side barrier sheet situated between the sealing layer and the back surface protecting material,
the front-side barrier sheet includes a front surface covering portion covering an entire region of the front surface of the sealing layer,
the back-side barrier sheet includes a back surface covering portion covering an entire region of the back surface of the sealing layer, and
the front-side barrier sheet includes a front-side protruding portion protruding from an edge portion of the front surface covering portion and situated away from the front surface protecting material and the front-side protruding portion is joined to the back-side barrier sheet in a state of covering the surrounding end surface, or the back-side barrier sheet includes a back-side protruding portion protruding from an edge portion of the back surface covering portion and situated away from the back surface protecting material and the back-side protruding portion is joined to the front-side barrier sheet in a state of covering the surrounding end surface.

In this functional roof, the barrier layer includes the front surface covering portion, the back surface covering portion, and the front-side protruding portion or the back-side protruding portion and accordingly, occurrence of air bubbles in the sealing layer caused by gas or water vapor entering the sealing layer is inhibited.

### (Aspect 2)

The functional roof according to aspect 1, wherein
the back-side barrier sheet includes the back-side protruding portion, and
the back-side protruding portion includes
   an end surface covering portion covering the surrounding end surface, and
   a back-side sheet end portion joined to the front-side barrier sheet.

### (Aspect 3)

The functional roof according to aspect 2, wherein
the front-side barrier sheet includes a front-side extension portion extending from the edge portion of the front surface covering portion and joined to the front surface protecting material, and
the back-side sheet end portion is joined to the front-side extension portion.

### (Aspect 4)

The functional roof according to aspect 2, wherein the back-side sheet end portion is situated between the front surface covering portion and the sealing layer.

### (Aspect 5)

The functional roof according to aspect 1, wherein
the front-side barrier sheet includes the front-side protruding portion, and
the front-side protruding portion includes
   an end surface covering portion covering the surrounding end surface, and
   a front-side sheet end portion joined to the back-side barrier sheet.

### (Aspect 6)

The functional roof according to aspect 5, wherein
the back-side barrier sheet includes a back-side extension portion extending from the edge portion of the back surface covering portion and joined to the back surface protecting material, and
the front-side sheet end portion is joined to the back-side extension portion.

### (Aspect 7)

The functional roof according to aspect 5, wherein the front-side sheet end portion is situated between the back surface covering portion and the sealing layer.

### (Aspect 8)

The functional roof according to any one of aspects 1 to 7, wherein the front surface protecting material, the front surface covering portion, the sealing layer, the back surface covering portion, and the back surface protecting material have a shape bending so as to project in a direction from the back surface protecting material toward the front surface protecting material.

### (Aspect 9)

The functional roof according to any one of aspects 1 to 8, wherein flexural rigidity of the front surface protecting material is higher than flexural rigidity of the back surface protecting material.

### (Aspect 10)

A manufacturing method of a functional roof including a functional layer having a predetermined function, a sealing layer sealing the functional layer, a front surface protecting material composed of resin with light transmittance and protecting a front surface of the sealing layer, a back surface protecting material protecting a back surface of the sealing layer, and a barrier layer covering the sealing layer, the barrier layer including a front-side barrier sheet situated between the sealing layer and the front surface protecting material, and a back-side barrier sheet situated between the sealing layer and the back surface protecting material, the method comprising:

a stack forming step of forming a stack by stacking the front surface protecting material, the front-side barrier sheet, a plurality of sealing layer forming materials constituting the sealing layer and the functional layer situated in the plurality of sealing layer forming materials, the back-side barrier sheet, and the back surface protecting material;

a uniting step of forming the sealing layer sealing the functional layer by heating the stack and thus softening the plurality of sealing layer forming materials, and of forming the barrier layer covering the sealing layer by joining the front-side barrier sheet and the back-side barrier sheet to each other; and a hot press step of, after the uniting step, pressing the front surface protecting material, the sealing layer, the barrier layer, and the back surface protecting material while heating the front surface protecting material, the sealing layer, the barrier layer, and the back surface protecting material so that the front surface protecting material, the sealing layer, the barrier layer, and the back surface protecting material have a shape bending so as to project toward one side in a direction in which the front surface protecting material, the sealing layer, the barrier layer, and the back surface protecting material are stacked.

### (Aspect 11)

The manufacturing method of the functional roof according to aspect 10, wherein
in the stack forming step, the stack further including a hard coat layer is formed, the hard coat layer being composed of a material higher in hardness than a material of which the front surface protecting material is composed and covering a front surface of the front surface protecting material, and
in the hot press step, the hard coat layer, the front surface protecting material, the sealing layer, the barrier layer, and the back surface protecting material are pressed while heated.

It should be understood that the herein-disclosed embodiments are presented by way of illustration and example in every respect and are not to be taken by way of limitation. The scope of the present invention is not defined by the foregoing description of the embodiments but is defined by the claims, and further includes all changes within the purport and scope equivalent to the claims.

### REFERENCE SIGNS LIST

1 functional roof, 10 functional layer, 10a first main surface, 10b second main surface, 10c end surface, 20 sealing layer, 30 front surface protecting material, 32 flange portion, 40 back surface protecting material, 42 flange portion, 50 barrier layer, 50A front-side barrier sheet, 50B back-side barrier sheet, 50C front-side adhesion layer, 50D back-side adhesion layer, 51 front surface covering portion, 52 back surface covering portion, 53 back-side protruding portion, 53a end surface covering portion, 53b back-side sheet end portion, 54 front-side extension portion, 55 front-side protruding portion, 55a end surface covering portion, 55b front-side sheet end portion, 56 back-side extension portion, 70 shield portion, 101 plate-like member, 102 sheet, S1 front surface, S2 back surface, S3 surrounding end surface.

1. A functional roof comprising:
a functional layer having a predetermined function;
a sealing layer sealing the functional layer and including a front surface, a back surface, and a surrounding end surface that links the front surface and the back surface and surrounds a periphery of the functional layer in a ring manner;
a front surface protecting material composed of resin with light transmittance and protecting the front surface of the sealing layer;
a back surface protecting material protecting the back surface of the sealing layer; and
a barrier layer covering the sealing layer, wherein
the barrier layer includes
a front-side barrier sheet situated between the sealing layer and the front surface protecting material, and
a back-side barrier sheet situated between the sealing layer and the back surface protecting material,
the front-side barrier sheet includes a front surface covering portion covering an entire region of the front surface of the sealing layer,
the back-side barrier sheet includes a back surface covering portion covering an entire region of the back surface of the sealing layer, and
the front-side barrier sheet includes a front-side protruding portion protruding from an edge portion of the front surface covering portion and situated away from the front surface protecting material and the front-side protruding portion is joined to the back-side barrier sheet in a state of covering the surrounding end surface, or the back-side barrier sheet includes a back-side protruding portion protruding from an edge portion of the back surface covering portion and situated away from the back surface protecting material and the back-side protruding portion is joined to the front-side barrier sheet in a state of covering the surrounding end surface.

2. The functional roof according to claim 1, wherein
the back-side barrier sheet includes the back-side protruding portion, and
the back-side protruding portion includes
an end surface covering portion covering the surrounding end surface, and
a back-side sheet end portion joined to the front-side barrier sheet.

3. The functional roof according to claim 2, wherein
the front-side barrier sheet includes a front-side extension portion extending from the edge portion of the front surface covering portion and joined to the front surface protecting material, and
the back-side sheet end portion is joined to the front-side extension portion.

4. The functional roof according to claim 2, wherein the back-side sheet end portion is situated between the front surface covering portion and the sealing layer.

5. The functional roof according to claim 1, wherein
the front-side barrier sheet includes the front-side protruding portion, and
the front-side protruding portion includes
an end surface covering portion covering the surrounding end surface, and
a front-side sheet end portion joined to the back-side barrier sheet.

6. The functional roof according to claim 5, wherein
the back-side barrier sheet includes a back-side extension portion extending from the edge portion of the back surface covering portion and joined to the back surface protecting material, and
the front-side sheet end portion is joined to the back-side extension portion.

7. The functional roof according to claim 5, wherein the front-side sheet end portion is situated between the back surface covering portion and the sealing layer.

8. The functional roof according to claim 1, wherein the front surface protecting material, the front surface covering portion, the sealing layer, the back surface covering portion, and the back surface protecting material have a shape bending so as to project in a direction from the back surface protecting material toward the front surface protecting material.

9. The functional roof according to claim 1, wherein flexural rigidity of the front surface protecting material is higher than flexural rigidity of the back surface protecting material.

10. A manufacturing method of a functional roof including a functional layer having a predetermined function, a sealing layer sealing the functional layer, a front surface protecting material composed of resin with light transmittance and protecting a front surface of the sealing layer, a back surface protecting material protecting a back surface of the sealing layer, and a barrier layer covering the sealing layer, the barrier layer including a front-side barrier sheet situated between the sealing layer and the front surface protecting material, and a back-side barrier sheet situated between the sealing layer and the back surface protecting material, the method comprising:
a stack forming step of forming a stack by stacking the front surface protecting material, the front-side barrier sheet, a plurality of sealing layer forming materials constituting the sealing layer and the functional layer situated in the plurality of sealing layer forming materials, the back-side barrier sheet, and the back surface protecting material;
a uniting step of forming the sealing layer sealing the functional layer by heating the stack and thus softening the plurality of sealing layer forming materials, and of forming the barrier layer covering the sealing layer by joining the front-side barrier sheet and the back-side barrier sheet to each other; and
a hot press step of, after the uniting step, pressing the front surface protecting material, the sealing layer, the barrier layer, and the back surface protecting material while heating the front surface protecting material, the sealing layer, the barrier layer, and the back surface protecting material so that the front surface protecting material, the sealing layer, the barrier layer, and the back surface protecting material have a shape bending so as to project toward one side in a direction in which the front surface protecting material, the sealing layer, the barrier layer, and the back surface protecting material are stacked.

11. The manufacturing method of the functional roof according to claim 10, wherein
in the stack forming step, the stack further including a hard coat layer is formed, the hard coat layer being composed of a material higher in hardness than a material of which the front surface protecting material is composed and covering a front surface of the front surface protecting material, and
in the hot press step, the hard coat layer, the front surface protecting material, the sealing layer, the barrier layer, and the back surface protecting material are pressed while heated.
